(19) United States
(12) Patent Application Publication
(10) Pub. No.: US 2026/0033364 A1
(43) Pub. Date: Jan. 29, 2026

(54) PACKAGE INTERCONNECT STRUCTURE

(71) Applicant: QUALCOMM Incorporated, San Diego, CA (US)

(72) Inventors: Aniket PATIL, San Diego, CA (US); Joan Rey Villarba BUOT, Escondido, CA (US); Zhijie WANG, San Diego, CA (US)

(21) Appl. No.: 19/222,592

(22) Filed: May 29, 2025

Related U.S. Application Data
(63) Continuation-in-part of application No. 18/784,420, filed on Jul. 25, 2024.
(63) Continuation-in-part of application No. 18/784,654, filed on Jul. 25, 2024.

(51) Int. Cl. H01L 23/498; H01L 21/48

(52) U.S. Cl. CPC H01L 23/49838; H01L 21/4846; H01L 23/49811

(57) ABSTRACT

Disclosed are package interconnect structures and semiconductor packages that include package interconnect structures. In conventional ball grid array (BGA) packages, circularly shaped BGA solder balls are used interconnect to a printed circuit board (PCB). Due to the minimum pitch requirements, the circular shapes of the solder balls means that the sizes of the solder balls are made small, which in turn reduces current carrying capacities. It is proposed to address this issue by providing non-circular interconnects. This can increase the sizes of the interconnects while maintaining minimum pitch requirements. As a result, power delivery network (PDN) performance can be increased.

### CROSS-REFERENCE TO RELATED APPLICATION

The present Application for Patent Is a Continuation in part of U.S. patent application Ser. No. 18/784,420 entitled “INTEGRATED DEVICE COMPRISING NON-CIRCULAR PILLAR INTERCONNECTS,” filed Jul. 25, 2024, assigned to the assignee hereof, and expressly incorporated herein by reference in its entirety. The present Application for Patent also is a Continuation in part of U.S. patent application Ser. No. 18/784,654 entitled “PACKAGE COMPRISING SUBSTRATE WITH VIA INTERCONNECTS COMPRISING NON-CIRCULAR PLANAR CROSS SECTION,” filed Jul. 25, 2024, assigned to the assignee hereof, and expressly incorporated herein by reference in its entirety.

### BACKGROUND OF THE DISCLOSURE

### 1. Field of the Disclosure

This disclosure relates generally to die packages or modules, and more specifically, but not exclusively, to novel package interconnect structure, e.g., for high speed applications.

### 2. Description of the Related Art

Integrated circuit (IC) technology has achieved great strides in advancing computing power through miniaturization of active components. In conventional integrated circuit (IC) packages, ball grid array (BGA) are used to interconnect the IC package to a printed circuit board (PCB) for example. Core ball pitch reduction is important to increase BGA density and improved power distribution network (PDN). However, the circular ball structure nature of conventional BGA presents a limit on the PDN improvement. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary package interconnect structure is disclosed. The package interconnect structure may comprise an interconnect substrate. The package interconnect structure may also comprise a plurality of first interconnects on a first surface of the interconnect substrate. At least one first interconnect may have a non-circular planar cross section. The package interconnect structure may further comprise a plurality of second interconnects on the first surface of the interconnect substrate.

A method of fabricating a package interconnect structure is disclosed. The method may comprise providing an interconnect substrate. The method may also comprise forming a plurality of first interconnects on a first surface of the interconnect substrate. At least one first interconnect may have a non-circular planar cross section. The method may further comprise forming a plurality of second interconnects on the first surface of the interconnect substrate.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B illustrate cross-sectional and bottom views of a conventional BGA package.

FIGS. 2A, 2B and 2C illustrate perspective, bottom and isometric views of a package interconnect structure in accordance with one or more aspects of the disclosure.

FIG. 2D illustrates a cross-sectional view of a package interconnect structure with optional land side capacitor in accordance with one or more aspects of the disclosure.

FIG. 3A illustrates BGA interconnects of a conventional BGA package to meet minimum pitch requirements.

FIG. 3B illustrates interconnects of a package interconnect structure to meet minimum pitch requirements in accordance with one or more aspects of the disclosure.

FIG. 4 illustrates a semiconductor package in accordance with one or more aspects of the disclosure.

FIG. 5 illustrates a flow of fabrication steps to fabricate and/or assemble package interconnect structure in accordance with one or more aspects of the disclosure.

FIGS. 6-8 illustrate flow charts of example methods of manufacturing a package interconnect structure in accordance with at one or more aspects of the disclosure.

FIG. 9 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are package interconnect structure and methods for fabricating the same. In an aspect, the package interconnect structure may comprise an interconnect substrate. The package interconnect structure may also comprise a plurality of first interconnects on a first surface of the interconnect substrate. At least one first interconnect may have a non-circular planar cross section. The package interconnect structure may further comprise a plurality of second interconnects on the first surface of the interconnect substrate. By providing a non-circular planar cross section for that least one first interconnect, bigger first connects may be provided while maintaining minimum pitch requirements. As a result, power distribution network performance may be enhanced.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

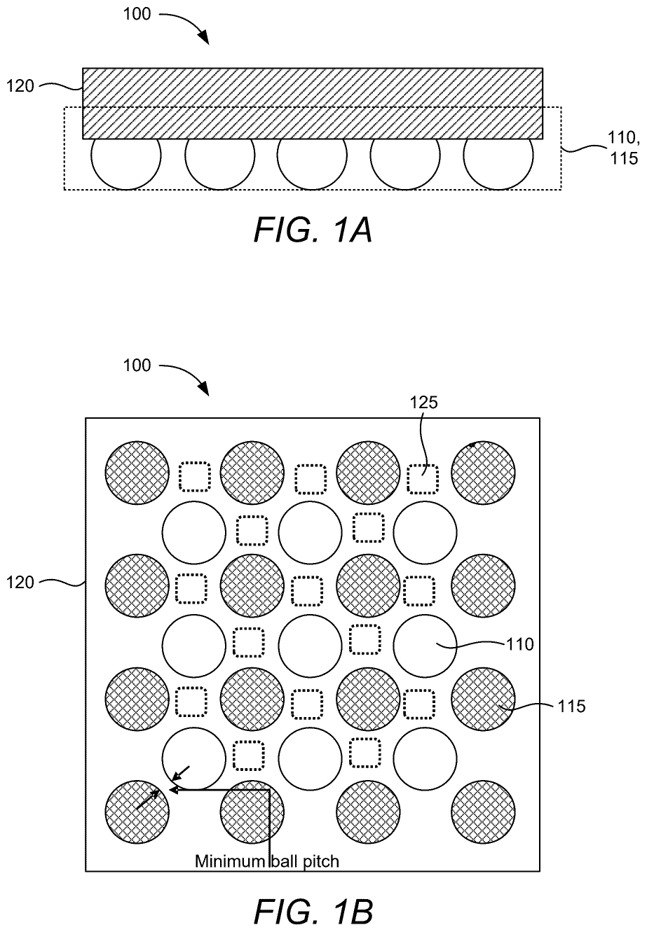

FIGS. 1A and 1B illustrate cross-sectional and bottom views of a conventional ball grid array (BGA) package 100. As seen in FIG. 1A, the conventional BGA package 100 includes a BGA substrate 120. The BGA package 100 also includes a plurality of first solder balls 110 and a plurality of second solder balls 115 formed on a lower surface of the BGA substrate 120.

The distribution of the first and second solder balls 110, 115 is better shown in FIG. 1B which illustrates the bottom view of the BGA package 100. As seen, there are multiple rows of the first solder balls 110 and multiple rows of the second solder balls 115. The rows of the first solder balls 110 are interleaved with the rows of the second solder balls. Typically, core PDN design includes alternate power and ground pins or balls placed on the BGA substrate 120. In FIG. 1B, it is assumed that the first solder balls 110 are power pins, and the second solder balls 115 are ground pins.

Core ball pitch reduction is an important factor to increase BGA density and to improve PDN across chip. Package ball solder resist opening (SRO) size plays an important role in minimum BGA pitch setup. In FIG. 1B, the minimum ball pitch between two solder balls—between one first solder ball 110 and one second solder ball 115—is shown. The spacing between any two solder balls must meet this minimum pitch requirement.

Note that the common BGA ball shape is circular for both the first and second solder balls 110, 115. Due to the circular ball geometry and the checkered board pattern ball arrangement, there are pockets that are pockets with empty regions—shown as empty pockets 125—that are without metal. These unused regions—the empty pockets 125—in the important core shadow means that available real estate is not used for PDN sensitive, e.g., in high speed core domains.

To address these and other issues of the BGA package, it is proposed to provide package interconnects that have non-circular planar cross sections to increase the sizes of the interconnects while maintaining minimum pitch requirements. In particular, it is proposed to shape the interconnects so that the empty pockets—and least some part there of—can be used. In this way, current carrying capacity can be increased, which thereby can improve PDN performances without violating the minimum pitch requirements.

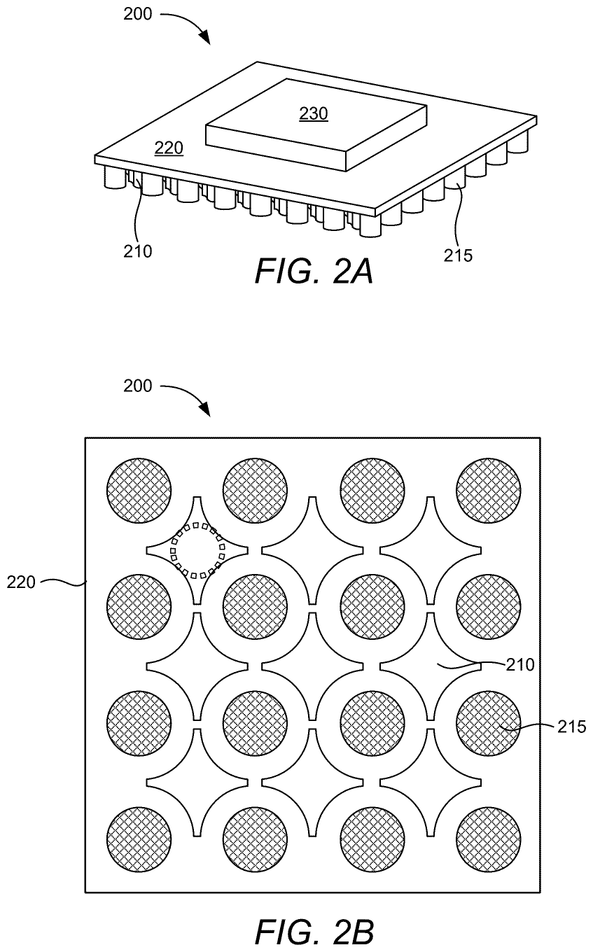

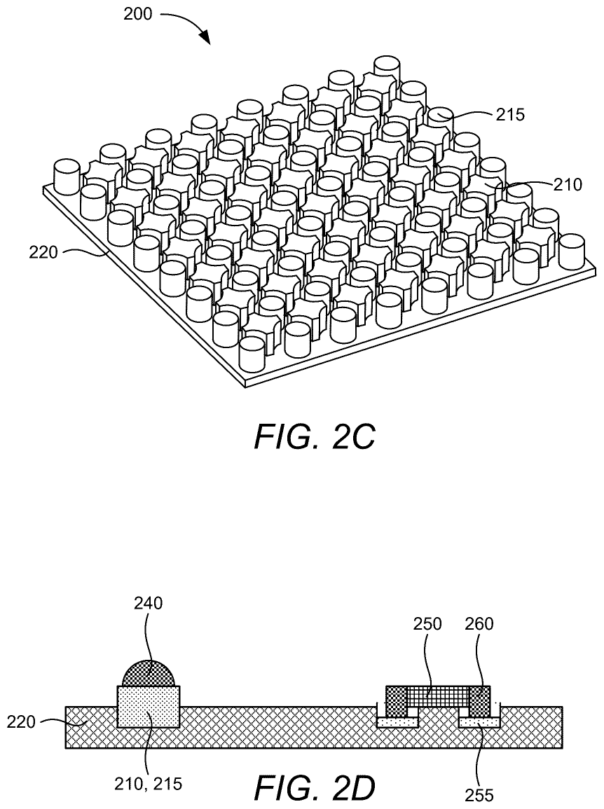

FIG. 2A illustrates a perspective view of a package interconnect structure 200 in accordance with one or more aspects. The package interconnect structure 200 (e.g., a BGA package) may comprise an interconnect substrate 220. The package interconnect structure 200 may also include a plurality of first interconnects 210 on a first surface (e.g., lower surface) of the interconnect substrate 220. The package interconnect structure 200 may further include a plurality of second interconnects 215, also on the first surface of the interconnect substrate 220.

A component 230, e.g., a die (e.g., system-on-chip, memory chip, etc.), passive components (e.g., capacitor, inductor, resistor, etc.) and so on may be provided on a second surface (e.g., upper surface) of the interconnect substrate 220 opposite the first surface. As an example, the component 230 may be a die 230. In an aspect, the interconnect substrate 220 may be a signal/power/ground redistribution layer (RDL). That is, the interconnect substrate 220 may be configured provide one or more electrical paths between one or more die bumps (not shown) of the die 230 and one or more of the first interconnects 210. Alternatively or in addition thereto, the interconnect substrate 220 may be configured provide one or more electrical paths between the one or more die bumps of the die 230 and one or more of the second interconnects 215.

Before proceeding further, the following should be noted. Terms or phrases such as “upper”, “lower”, “left”, “right”, “top”, “bottom”, etc. are used for convenience to describe the relative placements of the components in the figures. Unless otherwise clearly stated, these terms or phrases should NOT be taken to be limit the placements only to those absolute locations.

FIG. 2B illustrates a bottom view of the package interconnect structure 200. In an aspect, the plurality of first interconnects 210 and the plurality of second interconnects 215 may be interleaved, e.g., in a checkerboard pattern. For example, there can be one or more rows and/or columns of the first interconnects 210. In between the rows and/or columns of the of the first interconnects 210, there can be one or more rows and/or columns of the second interconnects 215.

In an aspect, one, some, or all of the first interconnects 210 may be configured to provide one or more electrical paths for power. Note that there can be paths for one or more powers or voltages (e.g., power 1 (or V1), power 2 (or V2), etc.). Alternatively or in addition thereto, one, some, or all of the second interconnects 215 may be configured to provide one or more electrical paths for ground. Note that there can be paths for one or more grounds (e.g., G1, G2, etc.).

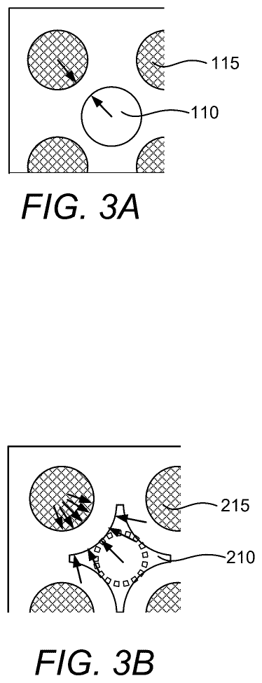

In an aspect, one, some, or all of the first interconnects 210 may have a non-circular planar cross section. Also, one, some, or all of the second interconnects 215 may have a circular planar cross section. Note that in FIG. 2B, for each second interconnect 215, it is closest to the first interconnect 210 having the non-circular planar cross section among all of the plurality of second interconnects 215. That is to say, the minimum pitch requirement is between a first interconnect 210 and a neighboring second interconnect 215. This will be explained further below when discussing FIGS. 3A and 3B.

An example of the non-circular planar cross section is a star-shaped planar cross section. More generally the non-circular planar cross section of the one, some, or all (i.e., at least one) of the first interconnects 210 may include a concave portion. When the first interconnects 210 are formed with such concave portions, the cross sectional area may be greater than the area of the circular cross section. This is shown in FIG. 2B. Note that one of the first interconnects 210 includes a dashed circle. The dashed circle may represent the cross sectional area of an interconnect if it were a circle, e.g., similar to the first solder ball 110 (e.g., see FIG. 1B). By having concave portions, at least some of the empty pockets 125 of the conventional BGA package 100 would now be used in the package interconnect structure 200. This means that the first interconnects 210 could be made larger and thus increase current carrying capacity, which in turn may improve PDN performance.

FIG. 2C illustrates an isometric view of the first surface of the package interconnect structure 200. As seen, the area of the first surface of the interconnect substrate 220 occupied by the first and second interconnects 210, 215 is quite significant due to the non-circular cross sections, greater than it would have been if all of the first and second interconnects 210, 215 would have had circular cross sections.

In an aspect, both the plurality of first interconnects 210 and the plurality of second interconnects 215 may be formed from copper (Cu). More generally, the first interconnects 210 and/or the second interconnects 215 may be formed from one or more metals whose melting point is greater than the melting point of solder. In this way, when solder reflow is performed—e.g., when attaching the package interconnect structure 200 to a printed circuit board (PCB)—the first and second interconnects 210, 215 may retain their physical form.

FIG. 2D illustrates a cross-sectional view of a package interconnect structure with optional land side capacitor (LSC) 250 in accordance with one or more aspects of the disclosure. In an aspect, the LSC 250 may be a multilayer ceramic chip capacitors (MLCC). As seen in FIG. 2D, the LSC 250 may be provided on the same side of the interconnect substrate 220 as the first and second interconnects 210, 215. That is, the LSC 250 may also be provided on the first surface of the interconnect substrate 220.

One or more LSC pad 250 (or MLCC pad 250) may be formed. Note that the LSC pads 255 may be formed within the interconnect substrate 220 such that the upper surfaces of the LSC pads 255 are below the upper surface of the interconnect substrate 220. One or more LSC solders 260 (or MLCC solders 260) may be formed on the corresponding LSC pads 255. The LSC 250 may be coupled to the LSC solders 260. Note that interconnect solders 240 may be formed on the first and second interconnects 210, 215.

FIG. 3A illustrates BGA interconnects of a conventional BGA package 100 to meet minimum pitch requirements. As seen before, when the first and second solder balls 110, 115 are all circular, there are unused empty pockets. Here, only one point of the first solder ball 110 is minimum pitch distance away from only one point of the second solder ball 115 as shown by the two arrows. The rest of the first and second solder balls 110, 115 are separated by a distance greater than the minimum pitch distance.

However, as seen in FIG. 3B, the first interconnect 210 includes concave portion. This allows multiple points of the first interconnect 210 to be minimum pitch distance away from multiple points of the second interconnect 215, as shown by multiples of arrows. It may be said that the concave portion of the first interconnect 210 has a constant distance from an arc portion of the at least one second interconnect 215. That is, the geometry of the interconnects (e.g., the star shape) can help in use of pin-to-pin keepout along the edge of the interconnects instead of one point in the existing conventional BGA package.

Compared to FIG. 3A, the interconnect cross sections of FIG. 3B can allow for more metal (e.g., Cu) volume for power, as much as 35% more. The concave shape (e.g., star shape) may enable utilizing most volume in available region near circular second interconnects 215 carrying ground. This means that the ball count for key core PDN rails can be reduced by as much as 35% as well, which means that the package area may be correspondingly reduced. Further, more Cu in the interconnect can help in thermal dissipation.

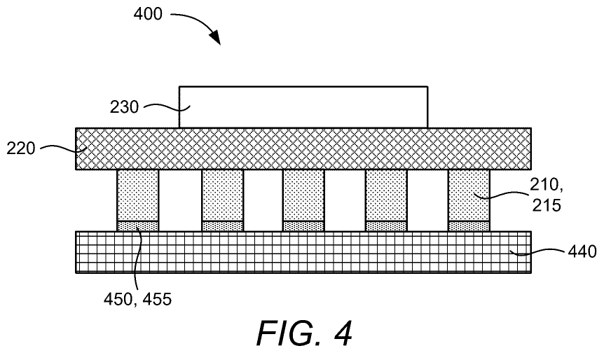

FIG. 4 illustrates a semiconductor package 400 in accordance with one or more aspects of the disclosure. The semiconductor package 400 may include the package interconnect structure 200. That is, the semiconductor package 400 may include an interconnect substrate 220, a plurality of first interconnects 210 on a first surface of the interconnect substrate 220, and a plurality of second interconnects 215 on the first surface of the interconnect substrate 220. One, some or all (i.e., at least one) first interconnects 210 may have non-circular planar cross sections, e.g., start-shaped, concave portion, etc. While not shown, one or more land side capacitors (LSC) 250 or multilayer ceramic chip capacitors (MLCC) 250, along with corresponding LSC pads 255 and LSC solders 260 may be provided on the first surface of the interconnect substrate 220. The semiconductor package 400 may also include a die 230 on a second surface of the interconnect substrate 220 opposite the first surface of the interconnect substrate 220.

The semiconductor package 400 may further include a printed circuit board (PCB) 440. The PCB 440 may be electrically coupled to the die 230 through one or more of the first interconnects 210, one or more of the second interconnects 215, and the interconnect substrate 220.

The PCB 440 may include a plurality of first pads 450 electrically coupled with the plurality of first interconnects 210. The PCB 440 may also include a plurality of second pads 455 electrically coupled with the plurality of second interconnects 215. One or more of the first pads 450 corresponding to one or more of the first interconnects 210 may have a corresponding non-circular planar cross sections. While not shown, in an aspect, there may be solder (e.g., for reflow attachment) between the first and second pads 450, 455 and the first and second interconnects 210, 215.

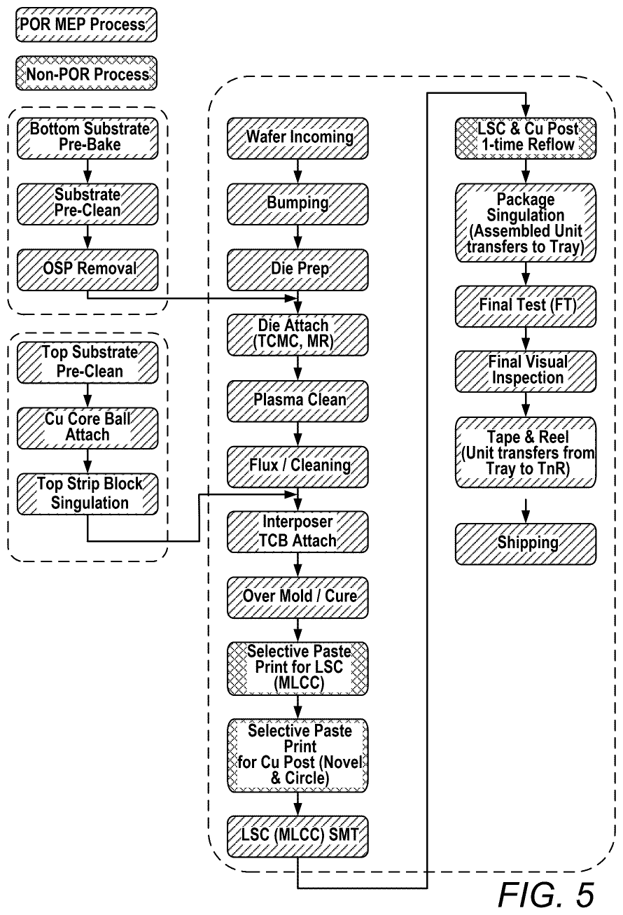

FIG. 5 illustrates a flow of fabrication steps to fabricate and/or assemble package interconnect structure in accordance with one or more aspects of the disclosure. It should be noted not all steps are required. It should also be noted that unless otherwise specifically indicated, the steps need not be performed in the order shown. Majority of the steps shown may be referred to as already being known. However, for the purposes of this disclosure, the steps of selective paste printing for Cu posts (e.g., formation of first and second interconnects 210, 215) may be particularly relevant. The selective paste printing for LSC (MLCC) 250 may also be relevant.

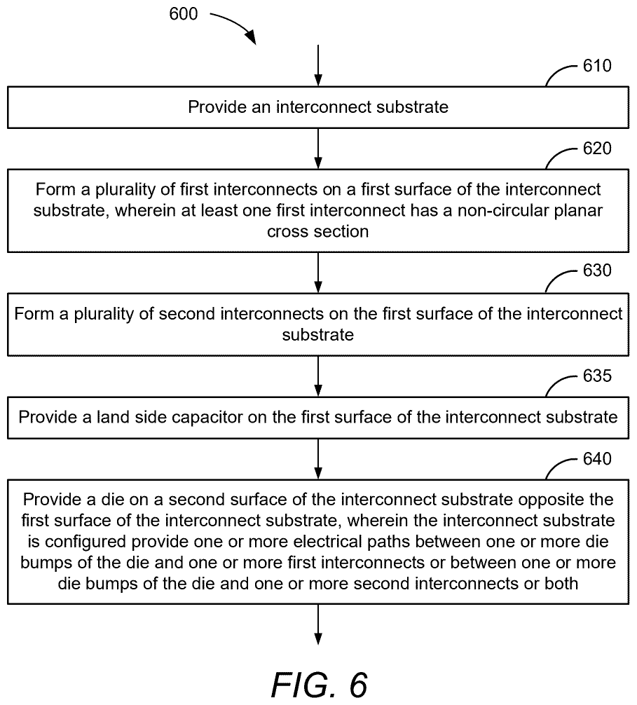

FIG. 6 illustrates a flow chart of an example method 600 of fabricating a package interconnect structure, such as the package interconnect structure 200, in accordance with one or more aspects of the disclosure.

In block 610, an interconnect substrate 220 may be provided.

In block 620, a plurality of first interconnects 210 may be formed on a first surface of the interconnect substrate 220. At least one first interconnect 210 may have a non-circular planar cross section.

In block 630, a plurality of second interconnects 215 may be formed on the first surface of the interconnect substrate 220.

In block 635, a land side capacitor (LSC) or a multilayer ceramic capacitor (MLCC) 250 may be provided on the first surface of the interconnect substrate 220.

In block 640, a die 230 may be provided on a second surface of the interconnect substrate 220 opposite the first surface of the interconnect substrate 220. The interconnect substrate 220 may be configured provide one or more electrical paths between one or more die bumps (not shown) of the die 230 and one or more first interconnects 210 or between one or more die bumps of the die 230 and one or more second interconnects 215 or both.

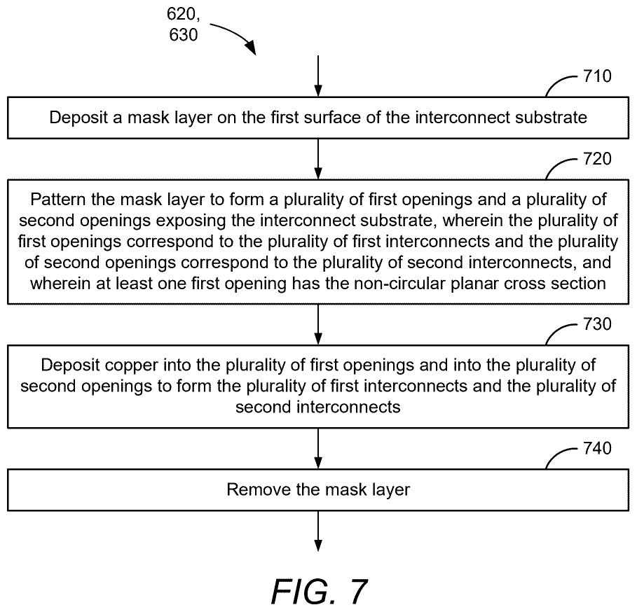

FIG. 7 illustrates an example of a process to implement block 620 of forming the plurality of first interconnects 210 and block 630 of forming the plurality of second interconnects 215.

In block 710, a mask (e.g., photo resist) layer may be deposited on the first surface of the interconnect substrate 220.

In block 720, the mask layer may be patterned to form a plurality of first openings and a plurality of second openings exposing the interconnect substrate 220. The plurality of first openings may correspond to the plurality of first interconnects 210 and the plurality of second openings may correspond to the plurality of second interconnects 215. One, some or all of the first opening may have the non-circular planar cross sections, similar to the planar cross sections of the corresponding one, some or all of the first interconnects 210.

In block 730, metal (e.g., copper) may be deposited into the plurality of first openings and into the plurality of second openings to form the plurality of first interconnects 210 and the plurality of second interconnects 215.

In block 740, the mask layer may be removed.

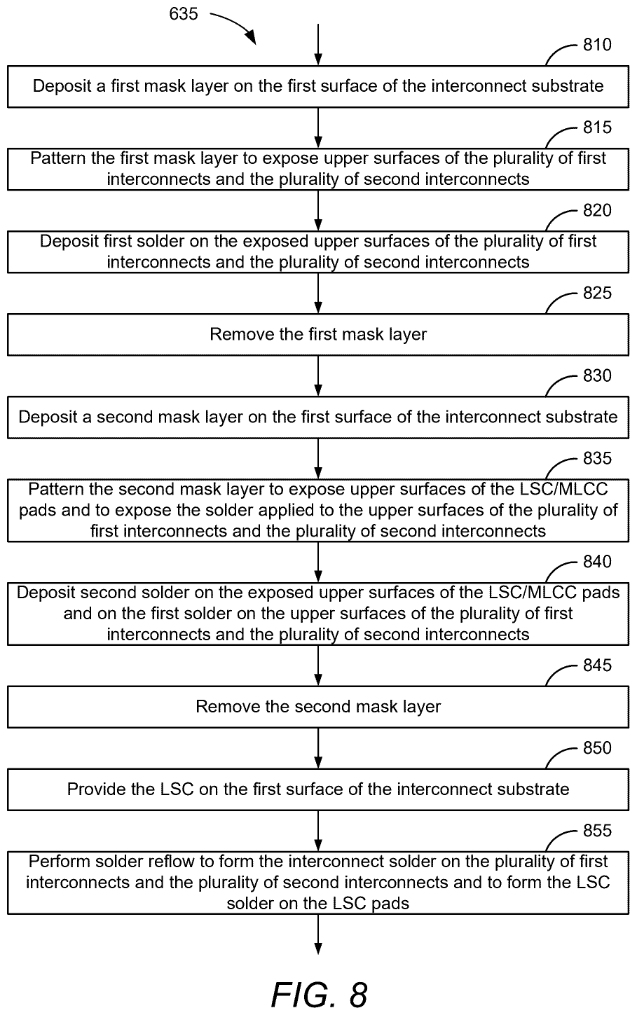

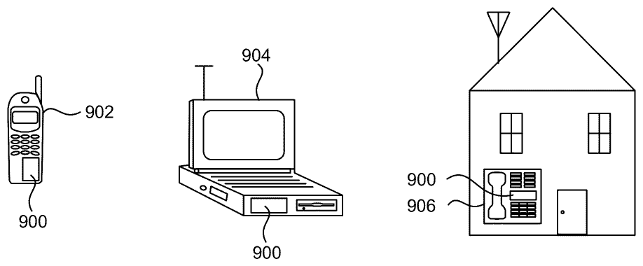

FIG. 8 illustrates an example of a process to implement block 635 of providing the LSC 250. In this instance, it may be assumed that the LSC pads 255 have been formed within the interconnect substrate 220. Recall that the upper surfaces of the LSC pads 255 may be below the upper surface of the interconnect substrate 220.

In block 810, a first mask (e.g., photo resist) layer may be deposited on the first surface of the interconnect substrate 220.

In block 815, the first mask layer may be patterned to expose upper surfaces of the plurality of first interconnects 210 and the plurality of second interconnects 215.

In block 820, first solder may be deposited on the exposed upper surfaces of the plurality of first interconnects 210 and the plurality of second interconnects 215.

In block 825, the first mask layer may be removed.

In block 830, a second mask (e.g., photo resist) layer may be deposited on the first surface of the interconnect substrate 220.

In block 835, the second mask layer may be patterned to expose upper surfaces of the LSC pads 255 and to expose the solder applied to the upper surfaces of the plurality of first interconnects 210 and the plurality of second interconnects 215.

In block 840, second solder may be deposited on the exposed upper surfaces of the LSC pads 255 and on the first solder on the upper surfaces of the plurality of first interconnects 210 and the plurality of second interconnects 215.

In block 845, the second mask layer may be removed.

In block 850, the LSC 250 may be provided on the first surface of the interconnect substrate 220.

In block 855, a solder reflow may be performed to form the interconnect solder 240 on the plurality of first interconnects 210 and the plurality of second interconnects 215 and to form the LSC solder 260 on the LSC pads 255;

The following should be noted regarding the flow indicated in FIGS. 6-8. Unless otherwise indicated, the flow of blocks do not necessarily limit the ordering in which the blocks may be performed. In other words, the blocks may be performed in any order that is logical.

FIG. 9 illustrates various electronic devices 900 that may be integrated with any of the aforementioned package interconnect structures and/or semiconductor packages in accordance with various aspects of the disclosure. For example, a mobile phone device 902, a laptop computer device 904, and a fixed location terminal device 906 may each be considered generally user equipment (UE) and may include one or more package interconnect structures (e.g., package interconnect structure 200) and/or one or more semiconductor packages (e.g., semiconductor package 400) as described herein. The devices 902, 904, 906 illustrated in FIG. 9 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A package interconnect structure, comprising: an interconnect substrate; a plurality of first interconnects on a first surface of the interconnect substrate, wherein at least one first interconnect has a non-circular planar cross section; and a plurality of second interconnects on the first surface of the interconnect substrate.
Clause 2: The package interconnect structure of clause 1, wherein the plurality of first interconnects are interleaved with the plurality of second interconnects.
Clause 3: The package interconnect structure of any of clauses 1-2, wherein at least one second interconnect has a circular planar cross section, and wherein the at least one second interconnect is closest to the at least one first interconnect among all of the plurality of second interconnects.
Clause 4: The package interconnect structure of clause 3, wherein the planar cross section of the at least one first interconnect includes a concave portion.
Clause 5: The package interconnect structure of clause 4, wherein the concave portion of the at least one first interconnect has a constant distance from an arc portion of the at least one second interconnect.
Clause 6: The package interconnect structure of any of clauses 1-5, wherein the at least one first interconnect has a star-shaped planar cross section.
Clause 7: The package interconnect structure of any of clauses 1-6, wherein one or more first interconnects are configured to provide one or more electrical paths for power, or wherein one or more second interconnects are configured to provide one or more electrical paths for ground, or both.
Clause 8: The package interconnect structure of any of clauses 1-7, wherein the plurality of first interconnects are formed from copper, or wherein the plurality of second interconnects are formed from copper, or both.
Clause 9: The package interconnect structure of any of clauses 1-8, further comprising: a die on a second surface of the interconnect substrate opposite the first surface of the interconnect substrate, wherein the interconnect substrate is configured provide one or more electrical paths between one or more die bumps of the die and one or more first interconnects or between one or more die bumps of the die and one or more second interconnects or both.
Clause 10: The package interconnect structure of any of clauses 1-9, wherein the package interconnect structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 11: A method of fabricating a package interconnect structure, the method comprising: providing an interconnect substrate; forming a plurality of first interconnects on a first surface of the interconnect substrate, wherein at least one first interconnect has a non-circular planar cross section; and forming a plurality of second interconnects on the first surface of the interconnect substrate.
Clause 12: The method of clause 1, wherein the plurality of first interconnects are interleaved with the plurality of second interconnects.
Clause 13: The method of any of clauses 11-12, wherein at least one second interconnect has a circular planar cross section, and wherein the at least one second interconnect is closest to the at least one first interconnect among all of the plurality of second interconnects.
Clause 14: The method of clause 13, wherein the planar cross section of the at least one first interconnect includes a concave portion.
Clause 15: The method of clause 14, wherein the concave portion of the at least one first interconnect has a constant distance from an arc portion of the at least one second interconnect.
Clause 16: The method of any of clauses 11-15, wherein the at least one first interconnect has a star-shaped planar cross section.
Clause 17: The method of any of clauses 11-16, wherein one or more first interconnects are configured to provide one or more electrical paths for power, or wherein one or more second interconnects are configured to provide one or more electrical paths for ground, or both.
Clause 18: The method of any of clauses 11-17, wherein the plurality of first interconnects are formed from copper, or wherein the plurality of second interconnects are formed from copper, or both.
Clause 19: The method of any of clauses 11-18, further comprising: providing a die on a second surface of the interconnect substrate opposite the first surface of the interconnect substrate, wherein the interconnect substrate is configured provide one or more electrical paths between one or more die bumps of the die and one or more first interconnects or between one or more die bumps of the die and one or more second interconnects or both.
Clause 20: The method of any of clauses 11-19, wherein forming the plurality of first interconnects and forming the plurality of second interconnects comprise: depositing a mask layer on the first surface of the interconnect substrate; patterning the mask layer to form a plurality of first openings and a plurality of second openings exposing the interconnect substrate, wherein the plurality of first openings correspond to the plurality of first interconnects and the plurality of second openings correspond to the plurality of second interconnects, and wherein at least one first opening has the non-circular planar cross section; depositing metal into the plurality of first openings and into the plurality of second openings to form the plurality of first interconnects and the plurality of second interconnects; and removing the mask layer.
Clause 21: The method of any of clauses 11-20, further comprising: providing a land side capacitor (LSC) on the first surface of the interconnect substrate, wherein one or more LSC pads are formed within the interconnect substrate, and upper surfaces of the LSC pads are below the upper surface of the interconnect substrate, and wherein providing the LSC comprises: depositing a first mask layer on the first surface of the interconnect substrate; patterning the first mask layer to expose upper surfaces of the plurality of first interconnects and the plurality of second interconnects; depositing a first solder on the exposed upper surfaces of the plurality of first interconnects and the plurality of second interconnects; removing the first mask layer; depositing a second mask layer on the first surface of the interconnect substrate; patterning the second mask layer to expose upper surfaces of the LSC pads and to expose the solder applied to the upper surfaces of the plurality of first interconnects and the plurality of second interconnects; depositing second solder on the exposed upper surfaces of the LSC pads and on the first solder on the upper surfaces of the plurality of first interconnects and the plurality of second interconnects; removing the second mask layer; providing the LSC on the first surface of the interconnect substrate; and performing a solder reflow to form an interconnect solder on the plurality of first interconnects and the plurality of second interconnects and to form an LSC solder on the LSC pads.
Clause 22: A semiconductor package, comprising: an interconnect substrate; a plurality of first interconnects on a first surface of the interconnect substrate, wherein at least one first interconnect has a non-circular planar cross section; a plurality of second interconnects on the first surface of the interconnect substrate; a die on a second surface of the interconnect substrate opposite the first surface of the interconnect substrate; and a printed circuit board (PCB) electrically coupled to the die through one or more first interconnects, one or more second interconnects, and the interconnect substrate.
Clause 23: The semiconductor package of clause 22, wherein the PCB includes: a plurality of first pads electrically coupled with the plurality of first interconnects; and a plurality of second pads electrically coupled with the plurality of second interconnects, wherein at least one first pad corresponding to the at least one first interconnect has a corresponding non-circular planar cross section.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A package interconnect structure, comprising:
an interconnect substrate;
a plurality of first interconnects on a first surface of the interconnect substrate, wherein at least one first interconnect has a non-circular planar cross section; and
a plurality of second interconnects on the first surface of the interconnect substrate.

2. The package interconnect structure of claim 1, wherein the plurality of first interconnects are interleaved with the plurality of second interconnects.

3. The package interconnect structure of claim 1,
wherein at least one second interconnect has a circular planar cross section, and
wherein the at least one second interconnect is closest to the at least one first interconnect among all of the plurality of second interconnects.

4. The package interconnect structure of claim 3, wherein the planar cross section of the at least one first interconnect includes a concave portion.

5. The package interconnect structure of claim 4, wherein the concave portion of the at least one first interconnect has a constant distance from an arc portion of the at least one second interconnect.

6. The package interconnect structure of claim 1, wherein the at least one first interconnect has a star-shaped planar cross section.

7. The package interconnect structure of claim 1,
wherein one or more first interconnects are configured to provide one or more electrical paths for power, or
wherein one or more second interconnects are configured to provide one or more electrical paths for ground, or
both.

8. The package interconnect structure of claim 1,
wherein the plurality of first interconnects are formed from copper, or
wherein the plurality of second interconnects are formed from copper, or both.

9. The package interconnect structure of claim 1, further comprising:
a die on a second surface of the interconnect substrate opposite the first surface of the interconnect substrate,
wherein the interconnect substrate is configured provide one or more electrical paths between one or more die bumps of the die and one or more first interconnects or between one or more die bumps of the die and one or more second interconnects or both.

10. The package interconnect structure of claim 1, wherein the package interconnect structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

11. A method of fabricating a package interconnect structure, the method comprising:
providing an interconnect substrate;
forming a plurality of first interconnects on a first surface of the interconnect substrate, wherein at least one first interconnect has a non-circular planar cross section; and
forming a plurality of second interconnects on the first surface of the interconnect substrate.

12. The method of claim 11, wherein the plurality of first interconnects are interleaved with the plurality of second interconnects.

13. The method of claim 11,
wherein at least one second interconnect has a circular planar cross section, and
wherein the at least one second interconnect is closest to the at least one first interconnect among all of the plurality of second interconnects.

14. The method of claim 13, wherein the planar cross section of the at least one first interconnect includes a concave portion.

15. The method of claim 11,
wherein one or more first interconnects are configured to provide one or more electrical paths for power, or
wherein one or more second interconnects are configured to provide one or more electrical paths for ground, or
both.

16. The method of claim 11, further comprising:
providing a die on a second surface of the interconnect substrate opposite the first surface of the interconnect substrate,
wherein the interconnect substrate is configured provide one or more electrical paths between one or more die bumps of the die and one or more first interconnects or between one or more die bumps of the die and one or more second interconnects or both.

17. The method of claim 11, wherein forming the plurality of first interconnects and forming the plurality of second interconnects comprise:
depositing a mask layer on the first surface of the interconnect substrate;
patterning the mask layer to form a plurality of first openings and a plurality of second openings exposing the interconnect substrate, wherein the plurality of first openings correspond to the plurality of first interconnects and the plurality of second openings correspond to the plurality of second interconnects, and wherein at least one first opening has the non-circular planar cross section;
depositing copper into the plurality of first openings and into the plurality of second openings to form the plurality of first interconnects and the plurality of second interconnects; and
removing the mask layer.

18. The method of claim 11, further comprising:
providing a land side capacitor (LSC) on the first surface of the interconnect substrate,
wherein one or more LSC pads are formed within the interconnect substrate, and upper surfaces of the LSC pads are below the upper surface of the interconnect substrate, and
wherein providing the LSC comprises:
depositing a first mask layer on the first surface of the interconnect substrate;
patterning the first mask layer to expose upper surfaces of the plurality of first interconnects and the plurality of second interconnects;
depositing a first solder on the exposed upper surfaces of the plurality of first interconnects and the plurality of second interconnects;
removing the first mask layer;
depositing a second mask layer on the first surface of the interconnect substrate;
patterning the second mask layer to expose upper surfaces of the LSC pads and to expose the solder applied to the upper surfaces of the plurality of first interconnects and the plurality of second interconnects;
depositing second solder on the exposed upper surfaces of the LSC pads and on the first solder on the upper surfaces of the plurality of first interconnects and the plurality of second interconnects;
removing the second mask layer;
providing the LSC on the first surface of the interconnect substrate; and
performing a solder reflow to form an interconnect solder on the plurality of first interconnects and the plurality of second interconnects and to form an LSC solder on the LSC pads.

19. A semiconductor package, comprising:
an interconnect substrate;
a plurality of first interconnects on a first surface of the interconnect substrate, wherein at least one first interconnect has a non-circular planar cross section;
a plurality of second interconnects on the first surface of the interconnect substrate;
a die on a second surface of the interconnect substrate opposite the first surface of the interconnect substrate; and
a printed circuit board (PCB) electrically coupled to the die through one or more first interconnects, one or more second interconnects, and the interconnect substrate.

20. The semiconductor package of claim 19, wherein the PCB includes:
a plurality of first pads electrically coupled with the plurality of first interconnects; and
a plurality of second pads electrically coupled with the plurality of second interconnects,
wherein at least one first pad corresponding to the at least one first interconnect has a corresponding non-circular planar cross section.
